(19) United States
(12) Patent Application Publication
(10) Pub. No.: US 2014/0320777 A1
(43) Pub. Date: Oct. 30, 2014

(54) DISPLAY DEVICE SUBSTRATE AND DISPLAY DEVICE INCLUDING THE SAME

(71) Applicant: Sharp Kabushiki Kaisha, Osaka-shi, Osaka (JP)

(72) Inventor: Yasumori Fukushima, Osaka-shi (JP)

(21) Appl. No.: 14/360,688

(22) PCT Filed: Nov. 21, 2012
(86) PCT No.: PCT/JP2012/007488

§ 371 Date: May 27, 2014

(30) Foreign Application Priority Data
Nov. 29, 2011 (JP) 2011-260556

(51) Int. Cl. G02F 1/1333; G02F 1/1368; H01L 27/12; G02F 1/1362

(52) U.S. Cl. CPC G02F 1/133305; G02F 1/136277; G02F 1/1368; H01L 27/1214
USPC 349/43; 257/59

(57) ABSTRACT

A liquid crystal display device (1) includes a plastic substrate (6) having flexibility, and a TFT substrate (2) formed on the plastic substrate (6) and including a display element layer (7) having a TFT. The thickness of the plastic substrate (6) is 5-20 μm, and the relationship 0≦D≦(2800×S^{-1.13})/T is satisfied, where The is the thickness [μm] of the plastic substrate (6), S is the linear expansion coefficient [ppm/K] of resin forming the plastic substrate (6), and D is the elasticity modulus [GPa] of the resin.

### TECHNICAL FIELD

The present invention relates to display device substrates such as TFT substrates including plastic substrates.

### BACKGROUND ART

In recent years, in the field of display including electronic books, electronic notes, electronic newspapers, digital signage, etc., great attention has been directed towards display devices using plastic substrates which are more advantageous in terms of heat resistance, flexibility, shock resistance, and lightweight properties than glass substrates, and has a possibility of creating new display devices which cannot be obtained in display using glass substrates.

As an example of such display devices, a liquid crystal display device including a pair of substrates facing each other (i.e., a thin film transistor (TFT) substrate and a color filter (CF) substrate) and a liquid crystal layer between the pair of substrates has been proposed.

In the liquid crystal display device, the TFT substrate includes a plastic substrate made of polyimide resin, and the like and having flexibility and a display element layer provided on the plastic substrate and including TFTs serving as switching elements. The CF substrate includes a plastic substrate and a CF element layer provided on the plastic substrate.

To fabricate a liquid crystal display device including such plastic substrates, first, plastic substrates are each formed on a glass substrate serving as a support substrate. Next, a TFT substrate including a display element layer formed on the plastic substrate, and a CF substrate including a CF element layer formed on the plastic substrate are fabricated. Then, the TFT substrate is bonded to the CF substrate. After that, back faces of the glass substrates are irradiated with a laser beam to remove the glass substrates, thereby fabricating the liquid crystal display device (see e.g., Patent Document 1).

### CITATION LIST

### Patent Document

Patent Document 1: Japanese Patent Publication No. 2010-32768

### SUMMARY OF THE INVENTION

### Technical Problem

In the display device described in the Patent Document 1, a high-temperature (about 300° C.) process has to be performed in the step of forming the plastic substrates on the glass substrates and in the step of forming a gate insulating film and a semiconductor layer on the display element layer.

At this time, the glass substrate and the plastic substrate formed on the glass substrate and made of a polyimide film have different linear expansion coefficients. Therefore, due to differences in stretchability of the glass substrate and plastic substrate, the glass substrate on which the plastic substrate has been formed has a warp or waviness. When the degree of deformation (warp, waviness, etc.) of the glass substrate increases, the handleability of the substrates significantly decreases in each of steps for forming the display element layer, which results in an undesirable defect such as breakage of the substrates, thereby reducing productivity.

Thus, the present invention was devised in view of the above-described problems, and it is an object of the present invention to provide a display device substrate in which deformation such as a warp or waviness of a support substrate on which a plastic substrate has been formed can be effectively reduced, and a reduction in productivity of a TFT substrate can be prevented, and a display device using the same.

### Solution to the Problem

To achieve the object, an example display device substrate of the present invention includes: a plastic substrate having flexibility; and a display element layer provided on the plastic substrate and having a switching element, wherein the plastic substrate has a thickness of 5-20 μm, and the following expression is satisfied:

### (Expression 1)

0≦D≦(2800×S^{-1.13})/T (1)

where

T is the thickness [μm] of the plastic substrate, S is a linear expansion coefficient [ppm/K] of resin forming the plastic substrate, and D is an elasticity modulus [GPa] of the resin.

With this configuration, even when a plastic substrate is formed on a glass substrate in the step of forming the display device substrate, it is possible to reduce deformation such as a warp or waviness of the glass substrate provided with the plastic substrate, the deformation being caused due to the difference in linear expansion coefficient between the glass substrate and the plastic substrate. Therefore, in the display element layer formation step, degradation in handleability of the glass substrate provided with the plastic substrate is reduced, so that breakage or the like of the display device substrate can be prevented. Therefore, a reduction in productivity of the display device substrate can be prevented.

In the display device substrate of the present invention, the resin may be polyimide resin.

With this configuration, the plastic substrate can be made of polyimide resin having excellent heat resistance.

In the display device substrate of the present invention, the polyimide resin may be one selected from the group consisting of aromatic polyimide resin, cyclic aliphatic polyimide resin, and fluorinated aromatic polyimide resin.

With this configuration, it is possible to form a plastic substrate having excellent transparency in the visible light region.

In the display device substrate of the present invention, the display element layer may include a base coat layer provided on a surface of the plastic substrate.

With this configuration, even when a base coat layer is provided on a surface of the plastic substrate, the plastic substrate in which the expression (1) is satisfied can reduce deformation such as unevenness of the surface of the base coat layer in the display device substrate fabrication step, the deformation being caused due to the difference in linear expansion coefficient between the plastic substrate and the base coat layer. Therefore, it is possible to prevent a reduction in transparency of the display device substrate.

The display device substrate of the present invention may further include a polarizing plate provided on a surface of the plastic substrate opposite to the display element layer, wherein the polarizing plate serves also as a holder preventing deformation of the display device substrate.

With this configuration, it is no longer necessary to provide a holder separately because the polarizing plate serves also as a holder. Thus, the number of components can be reduced, thereby reducing costs, and the total thickness of the display device can be reduced. In the display device substrate of the present invention, the switching element may be a TFT element.

The display device substrate of the present invention has excellent characteristics that degradation in handleability of the glass substrate provided with the plastic substrate is reduced, breakage or the like of the display device substrate is prevented, and a reduction in productivity of the display device substrate is prevented. Thus, the present invention is suitably used in a display device including a display device substrate, another display device substrate disposed to face the display device substrate, and a display medium layer provided between the display device substrate and the another display device substrate. The present invention is suitably used in the case where the display medium layer is a liquid crystal layer.

### Advantages of the Invention

According to the present invention, in a display device substrate including a plastic substrate having flexibility, breakage or the like of the display device substrate can be prevented, thereby preventing a reduction in productivity of the display device substrate.

### BRIEF DESCRIPTION OF THE DRAWINGS

FIG. 1 is a plan view illustrating an entire configuration of a liquid crystal display device according to an embodiment of the present invention.

FIG. 2 is a cross-sectional view illustrating the liquid crystal display device according to the embodiment of the present invention taken along the line A-A of FIG. 1.

FIG. 3 is an enlarged plan view illustrating a pixel section of a TFT substrate according to the embodiment of the present invention.

FIG. 4 is a cross-sectional view illustrating an entire configuration of the TFT substrate included in the liquid crystal display device according to the embodiment of the present invention.

FIG. 5 is a cross-sectional view illustrating an entire configuration of a display section of the liquid crystal display device according to the embodiment of the present invention.

FIG. 6 is a view illustrating the relationship of the amount of warping of a glass substrate provided with a plastic substrate used in the TFT substrate according to the embodiment of the present invention with respect to the linear expansion coefficient and the elasticity modulus of the plastic substrate.

FIG. 7 is a view illustrating a method for measuring the amount of warping of the glass substrate of FIG. 6.

FIG. 8 is a view illustrating the relationship among the linear expansion coefficient, the elasticity modulus, and the thickness of the plastic substrate, where the amount of warping of the glass substrate provided with the plastic substrate used in the TFT substrate according to the embodiment of the present invention is 1.5 mm.

FIG. 9 is a cross-sectional view illustrating a manufacturing method of a liquid crystal display device according to the embodiment of the present invention.

FIG. 10 is a cross-sectional view illustrating the manufacturing method of the liquid crystal display device according to the embodiment of the present invention.

FIG. 11 is a cross-sectional view illustrating the manufacturing method of the liquid crystal display device according to the embodiment of the present invention.

FIG. 12 is a cross-sectional view illustrating the manufacturing method of the liquid crystal display device according to the embodiment of the present invention.

FIG. 13 is a cross-sectional view illustrating the manufacturing method of the liquid crystal display device according to the embodiment of the present invention.

FIG. 14 is a cross-sectional view illustrating the manufacturing method of the liquid crystal display device according to the embodiment of the present invention.

FIG. 15 is a cross-sectional view illustrating a liquid crystal display device according to a variation of the present invention.

### DESCRIPTION OF EMBODIMENTS

Embodiments of the present invention will be described in detail below based on the drawings.

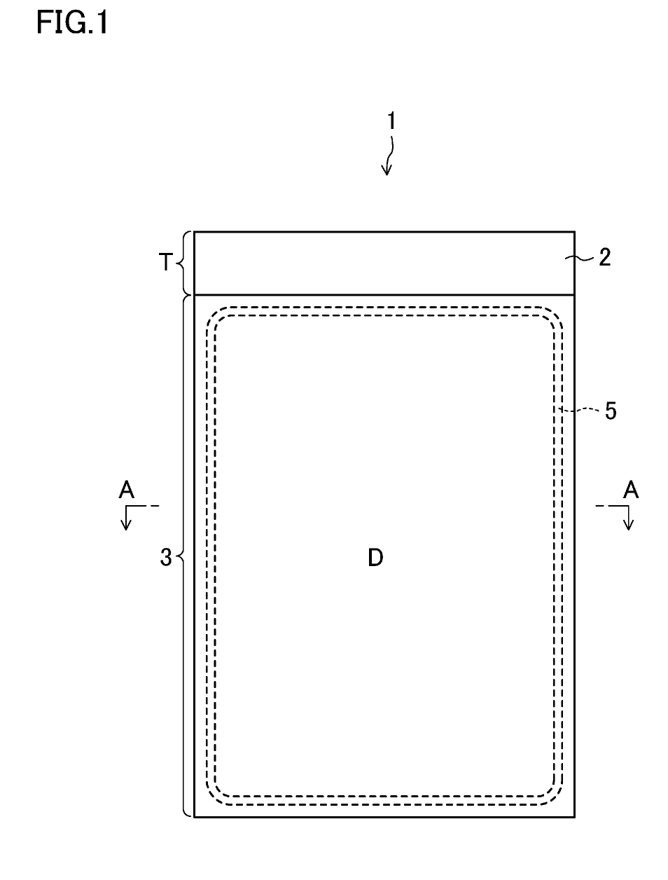

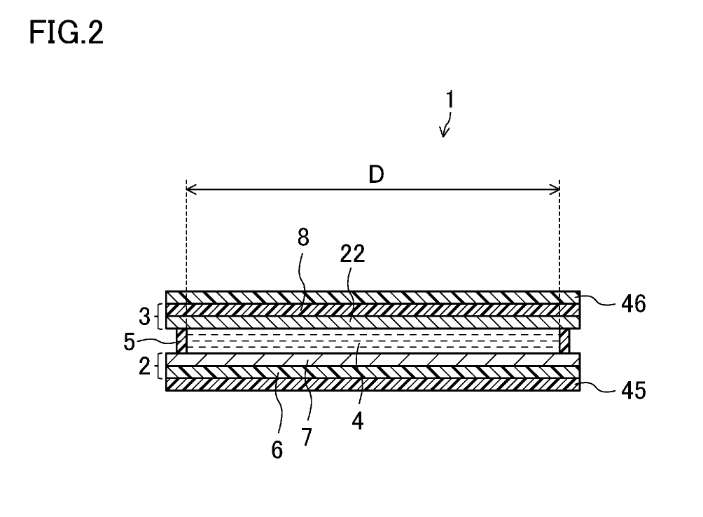

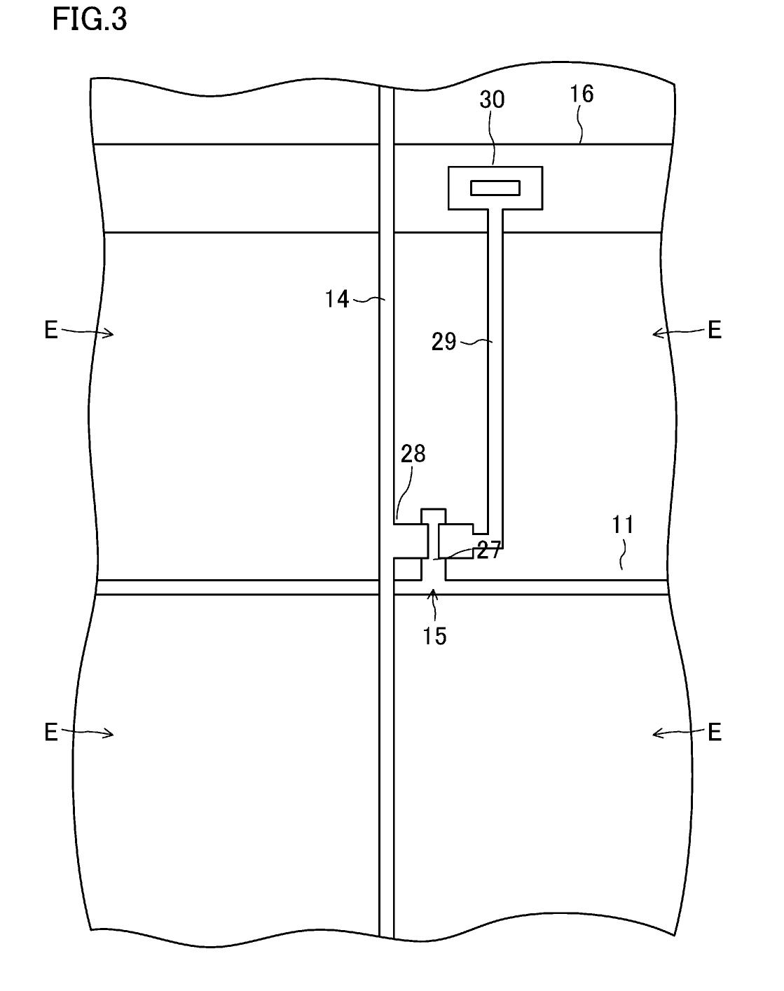

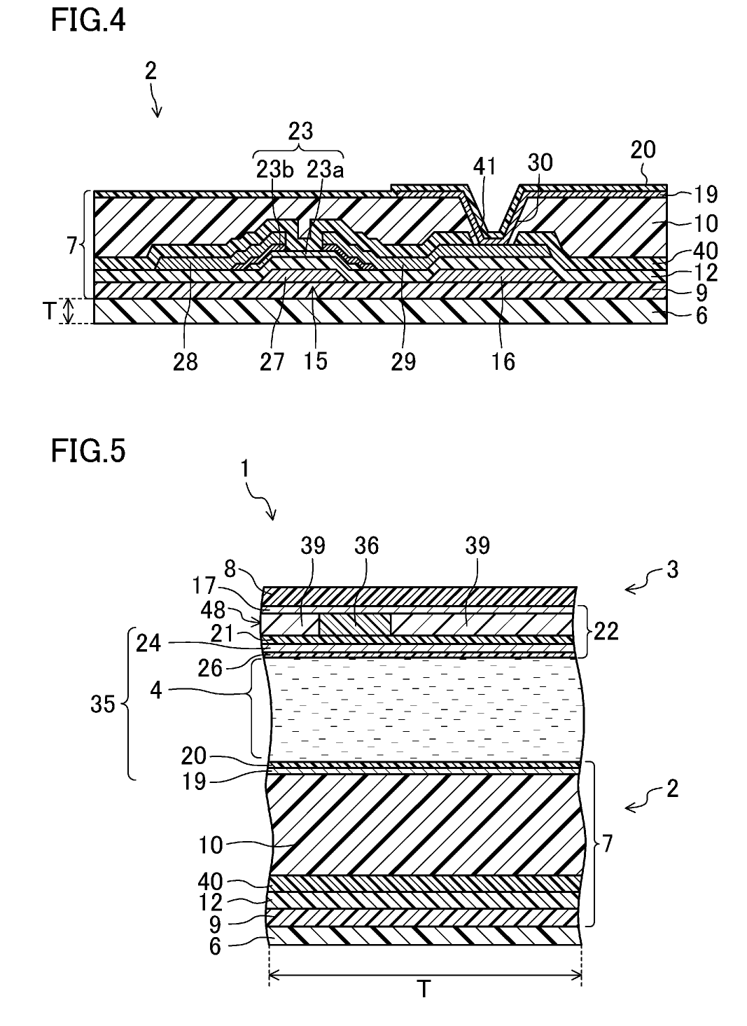

FIG. 1 is a plan view illustrating an entire configuration of a liquid crystal display device according to an embodiment of the present invention. FIG. 2 is a cross-sectional view taken along the line A-A of FIG. 1. FIG. 3 is an enlarged plan view illustrating a pixel section of a TFT substrate according to the embodiment of the present invention. FIG. 4 is a cross-sectional view illustrating an entire configuration of the TFT substrate included in the liquid crystal display device according to the embodiment of the present invention. FIG. 5 is a cross-sectional view illustrating an entire configuration of a display section of the liquid crystal display device according to the embodiment of the present invention. In the present embodiment, a liquid crystal display device will be described as an example of a display device.

As illustrated in FIGS. 1 and 2, a liquid crystal display device 1 includes a thin-film transistor (TFT) substrate 2 serving as a display device substrate provided with a plurality of TFTs serving as switching elements, and a CF substrate 3 serving as another display device substrate disposed to face the TFT substrate 2. The liquid crystal display device 1 further includes a liquid crystal layer 4 and a sealing material 5. The liquid crystal layer 4 serves as a display medium layer sandwiched between the TFT substrate 2 and the CF substrate 3. The sealing material 5 is sandwiched between the TFT substrate 2 and the CF substrate 3, and has a frame-like shape for bonding the TFT substrate 2 and the CF substrate 3 together and sealing the liquid crystal layer 4 between the TFT substrate 2 and the CF substrate 3.

The sealing material 5 extends around the liquid crystal layer 4, and the TFT substrate 2 and the CF substrate 3 are bonded together by the sealing material 5. Each of the TFT substrate 2 and the CF substrate 3 has a rectangular plate-like shape. The liquid crystal display device 1 further includes a plurality of photo spacers (not shown) for regulating a thickness (i.e., a cell gap) of the liquid crystal layer 4.

As illustrated in FIGS. 1 and 2, in the liquid crystal display device 1, a display region D for displaying an image is defined in a region surrounded by the sealing material 5, the TFT substrate 2 and the CF substrate 3 overlapping each other in the region. Here, in the display region D, a plurality of pixels E (see FIG. 3), each being a minimum unit of an image, are arranged in a matrix pattern.

As illustrated in FIG. 1, the liquid crystal display device 1 has a rectangular shape, and in the longitudinal direction of the liquid crystal display device 1, an upper edge of the TFT substrate 2 protrudes beyond the CF substrate 3. A terminal region T is defined in the protruding region. As illustrated in FIG. 1, the terminal region T is provided in the periphery of the display region D.

The terminal region T is provided with a plurality of terminals (not shown) and interconnects (not shown) each connected to a corresponding one of the terminals.

TFT substrate 2 includes a film-like plastic substrate 6 having flexibility. For example, a plastic substrate made of an organic material such as polyimide resin, poly-para-xylene resin, or acrylic resin can be used as the plastic substrate 6. In the present embodiment, it is preferable to use a plastic substrate made of polyimide resin which has in particular excellent heat resistance among these types of resins.

A display element layer 7 including TFTs and others is provided on the plastic substrate 6 of the TFT substrate 2.

Here, as illustrated in FIGS. 3 and 4, the display element layer 7 includes: a base coat layer (barrier layer) 9 provided on the plastic substrate 6; a plurality of gate interconnects 11 extending parallel to each other on the base coat layer 9; and a gate insulating film 12 covering the gate interconnects 11. The display element layer 7 further includes: a plurality of source interconnects 14 extending parallel to each other in a direction orthogonal to the gate interconnect 11 on the gate insulating film 12; a plurality of TFT elements 15 each provided at a corresponding one of intersections of the gate interconnects 11 and the source interconnects 14; and a plurality of auxiliary capacitor interconnects 16 each provided between adjacent ones of the gate interconnects 11 and extending parallel to each other. The display element layer 7 further includes: a passivation film 40 covering the gate interconnects 11, the source interconnects 14, and the TFT elements 15; a planarizing film 10 provided on the passivation film 40; a plurality of pixel electrodes 19 provided on the planarizing film 10 in a matrix pattern and each connected to a corresponding one of the TFT elements 15; and an alignment layer 20 covering the pixel electrodes 19.

As illustrated in FIG. 4, each TFT element 15 includes a gate electrode 27 which is a laterally extending portion of each gate interconnect 11, the gate insulating film 12 covering the gate electrode 27, a semiconductor layer 23 provided on the gate insulating film 12 in an island-like pattern at a position overlapping the gate electrode 27, and a source electrode 28 and a drain electrode 29 provided to face each other on the semiconductor layer 23.

The gate electrode 27 does not need to be a portion extending from the gate interconnect 11, but a layout in which part of the gate interconnect 11 is used as the gate electrode 27 may be possible.

Here, the source electrode 28 is a laterally extending portion of each source interconnect 14. As illustrated in FIG. 4, the drain electrode 29 is connected to the pixel electrode 19 via a contact hole 30 formed in the planarizing film 10.

The source electrode 28 does not need to be a portion extending from the source interconnect 14, but a layout in which part of the source interconnect 14 is used as the source electrode 28 may be possible.

As illustrated in FIG. 4, the semiconductor layer 23 includes a lower intrinsic amorphous silicon layer 23a and a phosphorus-doped n⁺ amorphous silicon layer 23b on the lower intrinsic amorphous silicon layer 23a. The intrinsic amorphous silicon layer 23a exposed from the source electrode 28 and the drain electrode 29 forms a channel region.

The drain electrode 29 and an auxiliary capacitor interconnect 16 overlap each other with the gate insulating film 12 interposed therebetween, thereby forming an auxiliary capacitor.

Examples of a material for forming the base coat layer 9 include silicon oxide (SiO₂), silicon nitride (SiNx, where x is a positive number), and silicon oxy nitride (SiNO). The base coat layer 9 may have a layered structure of these materials.

A material for forming the gate insulating film 12 is not specifically limited. The gate insulating film 12 can be made of, for example, silicon oxide (SiO₂), a material having a lower dielectric constant than silicon oxide such as SiOF or SiOC, silicon nitride (SiNx, where x represents a positive number) such as trisilicon tetranitride (Si₃N₄), silicon oxynitride (SiNO), titanium dioxide (TiO₂), dialuminum trioxide (Al₂O₃), tantalum oxide such as tantalum pentoxide (Ta₂O₅), or a material having a higher dielectric constant than silicon oxide such as hafnium dioxide (HfO₂) or zirconium dioxide (ZrO₂). The gate insulating film 12 may have a single layer structure, or may have a multilayer structure.

A material which comprises the planarizing film 10 is not specifically limited. The planarizing film 10 can be made of an insulative material such as silicon oxide (SiO₂) or silicon nitride (SiNx, where x is a positive number).

In order to achieve flatness of the surface, an insulative material such as an acrylic transparent resin material can be used as an interlayer insulating material. A layered structure these materials may be used, or the planarizing film 10 may be made of only the acrylic transparent resin material.

Similar to the TFT substrate 2, the CF substrate 3 includes a film-like plastic substrate 8 made of a resin material and having flexibility. For example, a plastic substrate made of an organic material such as polyimide resin, poly-para-xylene resin, or acrylic resin can be used as the plastic substrate 8. It is preferable to use a plastic substrate 8 made of in particular polyimide resin having excellent heat resistance.

For example, aromatic polyimide resin, aromatic (carboxylic acid component)-cyclic aliphatic (diamine component) polyimide resin, cyclic aliphatic (carboxylic acid component)-aromatic (diamine component) polyimide resin, cyclic aliphatic polyimide resin, fluorinated aromatic polyimide resin, etc. can be used as polyimide resin for forming the plastic substrates 6, 8.

The cyclic aliphatic polyimide resin in which no charge-transfer complex is formed in a molecule or between molecules and the fluorinated aromatic polyimide resin in which no charge-transfer complex is formed in a molecule or between molecules due to a structure containing fluorine increase the transparency of the plastic substrates 6,8 in the visible light region, and thus are suitable to transmission-type display devices.

The transparency of the plastic substrates 6, 8 is preferably, for example, such that the total luminous transmittance relative to the visible light range (wavelength range of 400-800 nm) is higher than or equal to about 80%.

On the plastic substrate 8 of the CF substrate 3, a CF element layer 22 is formed. Here, as illustrated in FIG. 5, the CF element layer 22 includes a base coat layer 17 provided on the plastic substrate 8, a color filter 48 provided on the base coat layer 17, and a planarizing film 21 provided on the color filter 48. The CF element layer 22 further includes a common electrode 24 provided on the planarizing film 21 to cover a reflective region of the color filter 48, a columnar photo spacer (not shown) provided on the common electrode 24, and an alignment layer 26 covering the common electrode 24 and the photo spacer.

As illustrated in FIG. 5, the color filter 48 includes a plurality of kinds of colored layers 39 (i.e., a red layer, a green layer, and a blue layer) each provided to a corresponding one of the pixels, and a black matrix 36 serving as a light shielding film. The black matrix 36 is provided between adjacent ones of the colored layers 39, and has a function of partitioning these plurality of kinds of colored layers 39.

The black matrix 36 is made of, for example, a metal material such as tantalum (Ta), chromium (Cr), molybdenum (Mo), nickel (Ni), titanium (Ti), copper (Cu), or aluminum (Al), a resin material in which black pigment such as carbon is dispersed, or a resin material in which colored layers of a plurality of colors each having a light-transmissive property are stacked. The photo spacer is made of, for example, acrylic photosensitive resin and is formed by photolithography.

In the present embodiment, the plastic substrates 6, 8 each have a thickness of 5-20 μm. This is because if the thickness is less than 5 μm, sufficient mechanical strength is not obtained, and for example, when the plastic substrates 6, 8 are removed from the glass substrates, breakage or the like of the plastic substrates 6, 8 may be caused. When the thickness is greater than 20 μm, costs are increased, and double refraction (retardation) increases in proportion to the thickness, so that display performance such as a viewing angle may be reduced.

The liquid crystal layer 4 includes, for example, nematic liquid crystals having electro-optic characteristics.

As illustrated in FIG. 5, in the display section of the liquid crystal display device 1, a transmissive region T is defined by the pixel electrode 19 made of a transparent electrode.

In the present embodiment, a liquid crystal display element 35 is provided on the TFT substrate 2. The liquid crystal display element 35 includes the pixel electrode 19, the liquid crystal layer 4 above the pixel electrode 19, and the common electrode 24 above the liquid crystal layer 4.

As illustrated in FIG. 2, a polarizing plate 45 is provided on a surface of the plastic substrate 6 of the TFT substrate 2 opposite to the display element layer 7. A polarizing plate 46 is provided on a surface of the plastic substrate 8 of the CF substrate 3 opposite to the CF element layer 22.

When the liquid crystal display device 1 having the configuration described above is a reflective liquid crystal display device, the reflective liquid crystal display device is configured such that light entering a reflective region R from the side of the CF substrate 3 is reflected by a reflective electrode 32.

The liquid crystal display device 1 is configured such that each of the pixel electrodes 19 forms a corresponding one of the pixels E, and in each pixel E, when the TFT element 15 is turned on by a gate signal sent from the gate interconnect 11, a source signal is sent from the source interconnect 14, so that a predetermined charge is written in the pixel electrode 19 through the source electrode 28 and the drain electrode 29, which causes a potential difference between the pixel electrode 19 and the common electrode 24, thereby applying a predetermined voltage to the liquid crystal layer 4.

The liquid crystal display device 1 is configured such that changes of the alignment of liquid crystal molecules depending on the magnitude of the applied voltage are used to adjust the reflectance of light entering from the side of the CF substrate 3, thereby displaying an image.

Here, a feature of the present embodiment is the use of a plastic substrate 6 in which the following expression (1) is satisfied.

(Expression 1)

0≦D≦(2800×S^{-1.13})/T (1)

where T is the thickness [μm] of the plastic substrate 6, S is the linear expansion coefficient [ppm/K] of polyimide resin forming the plastic substrate 6, and D is the elasticity modulus [GPa].

By using such a plastic substrate 6, it is possible, even in the case of forming the plastic substrate 6 on a glass substrate in a TFT substrate fabricating step, to reduce deformation such as a warp or waviness of the glass substrate provided with the plastic substrate 6, the deformation being caused due to the difference in linear expansion coefficient between the glass substrate and the plastic substrate 6.

Therefore, in the step of forming the display element layer 7, degradation in handleability of the glass substrate provided with the plastic substrate 6 is reduced, and thus breakage or the like of the TFT substrate 2 can be prevented, so that it is possible to prevent a reduction in productivity of the TFT substrate 2.

In the conventional display device, the linear expansion coefficient is different between the plastic substrate and the base coat layer formed on the plastic substrate. Thus, if the plastic substrate is largely stretched in forming the base coat layer, deformation such as unevenness of the surface of the base coat layer on the plastic substrate occurs, which results in a disadvantage that the transparency of the TFT substrate is reduced (white turbidity occurs).

On the other hand, in the present embodiment, the plastic substrate 6 in which the expression (1) is satisfied is used, so that it is possible to reduce deformation such as unevenness of the surface of the base coat layer 9 in the TFT substrate fabricating step, the deformation being caused due to the difference in linear expansion coefficient between the plastic substrate 6 and the base coat layer 9 formed on the plastic substrate 6. Therefore, it is possible to prevent a reduction in transparency of the TFT substrate 2.

Next, the expression (1) will be described.

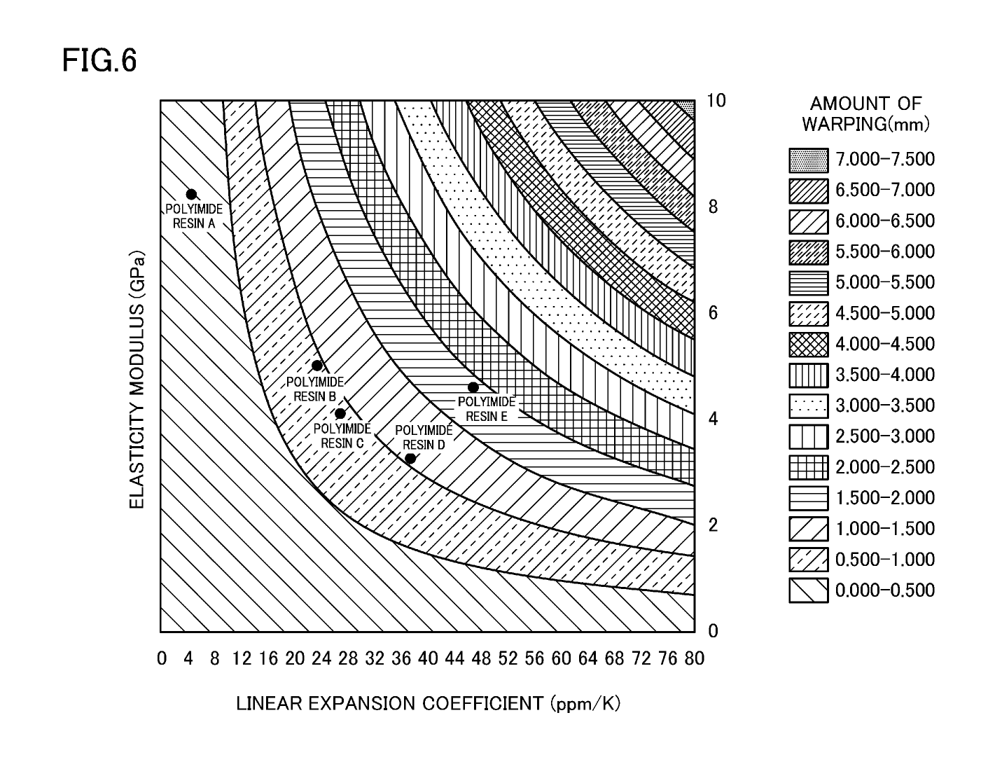

First, it was presumed that the amount of warping of a substrate including a glass substrate and a plastic substrate formed on the glass substrate depends on the linear expansion coefficients and the elasticity moduli of the glass substrate and the plastic substrate, the temperature in forming the plastic substrate, and the size of the glass substrate. In order to explain changes in the amount of warping of the substrate caused due to the linear expansion coefficients and the elasticity moduli, the amount of warping was calculated with reference to a concept of a warp of attached substrates of strength of materials (see Hiroshi Miyamoto, and one other person, “Strength of Materials,” Shokabo Publishing Co., Ltd., p 109). The result of the calculation is shown in FIG. 6.

Here, it was defined as a precondition that the thickness of the glass substrate was 0.7 mm, the length of the glass substrate was 400 mm, the width of the glass substrate was 320 mm, and the linear expansion coefficient of the glass substrate was 3.8 ppm/K. It was also defined that the thickness of the plastic substrate was 10 μm, and the difference between the room temperature and the temperature in forming layers (at the time of imidization reaction) was 300° C.

FIG. 6 shows that the amount of warping of the substrate depending on the linear expansion coefficient and the elasticity modulus is shown as isoquant curves.

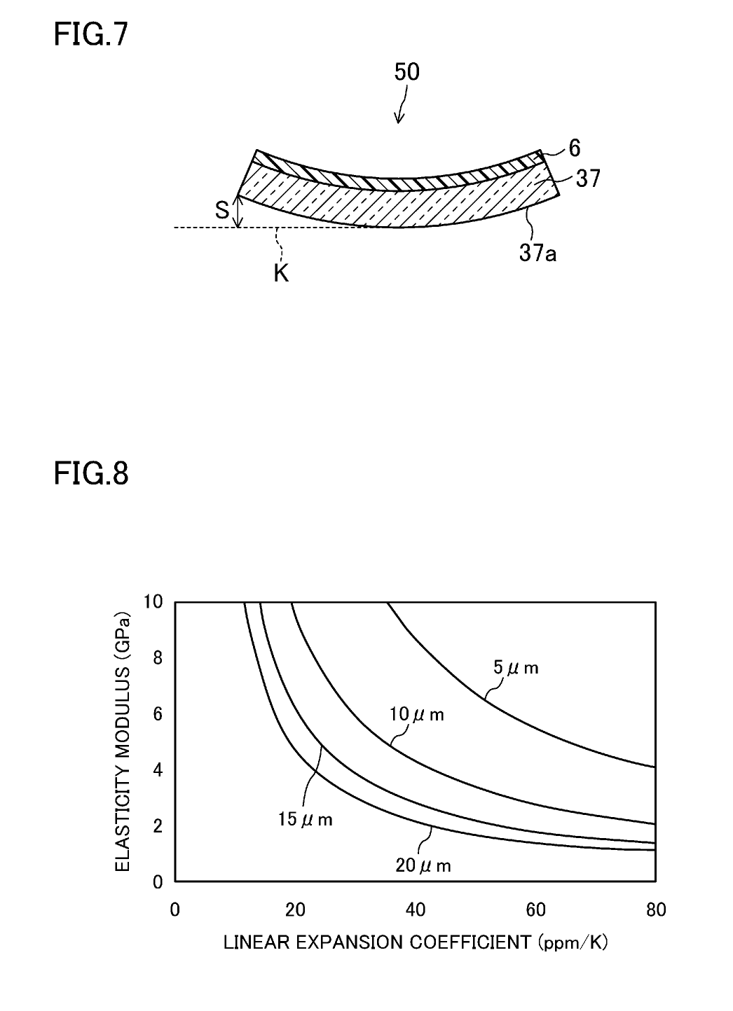

Next, polyimide resin having a linear expansion coefficient of 5 ppm/K and an elasticity modulus of 8.5 GPa (hereinafter referred to as “polyimide resin A”), polyimide resin having a linear expansion coefficient of 20 ppm/K and an elasticity modulus of 4.8 GPa (hereinafter referred to as “polyimide resin B”), polyimide resin having a linear expansion coefficient of 27 ppm/K and an elasticity modulus of 4.3 GPa (hereinafter referred to as “polyimide resin C”), polyimide resin having a linear expansion coefficient of 36 ppm/K and an elasticity modulus of 3.3 GPa (hereinafter referred to as “polyimide resin D”), and polyimide resin having a linear expansion coefficient of 48 ppm/K and an elasticity modulus of 4.8 GPa (hereinafter referred to as “polyimide resin E”) were formed as films on glass substrates 37 illustrated in FIG. 7, thereby forming plastic substrates 6, and the linear expansion coefficient and the elasticity modulus of each plastic substrate 6 were measured. The result of the measurement is shown in FIG. 6.

In a method for forming the plastic substrates 6 on the glass substrates 37, a silane coupling agent for ensuring adhesion was first applied to the glass substrates 37, and was then subjected to heat treatment. After that, each of organic solvents (dimethyl acetamide, N-methyl pyrrolidone, etc.) which contains a precursor (polyamide acid) of a corresponding one of polyimide resins A-E described above and serving as materials of the plastic substrates 6 was applied to a surface of an associated one of the glass substrates 37.

Next, the glass substrates 37 were heated at about 100° C. to volatilize the above-described organic solvents, and were then subjected to thermal treatment at 250-350° C. for one hour to cause imidization reaction, thereby obtaining substrates 50 each including a plastic substrate 6 (having a thickness of 10 μm) made of a corresponding one of polyimide resins A-E and formed on the glass substrate 37.

A plastic substrate 6 made of polyimide resin B and a plastic substrate 6 made of polyimide resin D were each formed on a glass substrates (having a length of 400 mm and a width of 320 mm) 37. The amount of warping of each substrate (a maximum distance S[mm] from the reference level K to a lower surface 37a of the glass substrate 37 shown in FIG. 7) was about 0.95 mm in the case of polyimide resin B, and about 1.1 mm in the case of polyimide resin D. Thus, it was confirmed that the amount of warp substantially matches the isoquant curves shown in FIG. 6.

Plastic substrates 6 of polyimide resins A, B, D, and E were each formed on a glass substrate (having a length of 400 mm and a width of 320 mm) 37, and then an inorganic film (silicon nitride film) was further formed on each plastic substrate 6. In this case, a white turbidity defect due to surface unevenness was observed only in the case of polyimide resin E. This is probably because the film of polyimide resin E has a high linear expansion coefficient.

When these results are taken into consideration, it is presumed with reference to FIG. 6 that a border specifying whether or not a white turbidity defect due to the amount of warping or surface unevenness of the substrate is observed lies between polyimide resin E and the other polyimide resins A-D. The larger the amount of warping of the substrate is, the more likely a defect such as a substrate transport defect occurs. From FIG. 6, the border seems to be at an amount of warping of about 1.5 mm. Therefore, when the amount of warping of a substrate including a glass substrate and a plastic substrate (having a thickness of 10 μm) made of polyimide resin formed on the glass substrate is less than or equal to 1.5 mm (i.e., in the range of the amount of warping of 0-1.5 mm in which the amount of warping in the case of using the above-described polyimide resins A-D is included), no white turbidity defect will be found, the handleability of the substrate will be excellent, and no defect such as breakage will occur in the substrate.

Next, the range of the thickness of the plastic substrate 6 formed on the glass substrate 37 was examined. FIG. 8 illustrates the relationship among the linear expansion coefficient, the elasticity modulus, and the thickness of the plastic substrate, where the amount of warping of the glass substrate provided with a plastic substrate used in the TFT substrate according to the embodiment of the present invention is 1.5 mm

In other words, the plastic substrate 6 has a thickness of 10 μm in FIG. 6 described above. However, the thickness of the plastic substrates 6 was changed to 5 μm, 15 μm, and 20 μm, and a figure similar to FIG. 6 was drawn. From the figure, an isoquant map in which the amount of warping at each of the thicknesses is 1.5 mm is extracted and plotted, thereby obtaining FIG. 8.

The reason why the thickness of the plastic substrates 6 is limited to 5-20 μm is as described above.

Here, the relationship illustrated in FIG. 8 was obtained in a manner similar to that described in FIG. 6 except that the thickness of the plastic substrates 6 formed on the glass substrate 37 was changed to 5 μm, 15 μm, and 20 μm.

FIG. 8 shows that the relationship between the linear expansion coefficient and the elasticity modulus of each thickness forms a curve, and the linear expansion coefficient and the elasticity modulus are inversely proportional to each other. When the linear expansion coefficient is constant, the elasticity modulus increases as the thickness of the plastic substrate decreases (i.e., there is an inversely proportional relationship between the elasticity modulus and the thickness).

When these results are taken into consideration, it is presumed that the following expression (2) is satisfied among the thickness T[μm] of the plastic substrate 6, the linear expansion coefficient [ppm/K]S of resin (polyimide resin) included in the plastic substrate 6, and the elasticity modulus [GPa]D.

(Expression 2)

D˜(A×S^{-α})/T (where A and α are constants) (2)

Constant A and constant α in the expression (2) are calculated based on the data of FIG. 8, thereby obtaining the relationship in the expression (1).

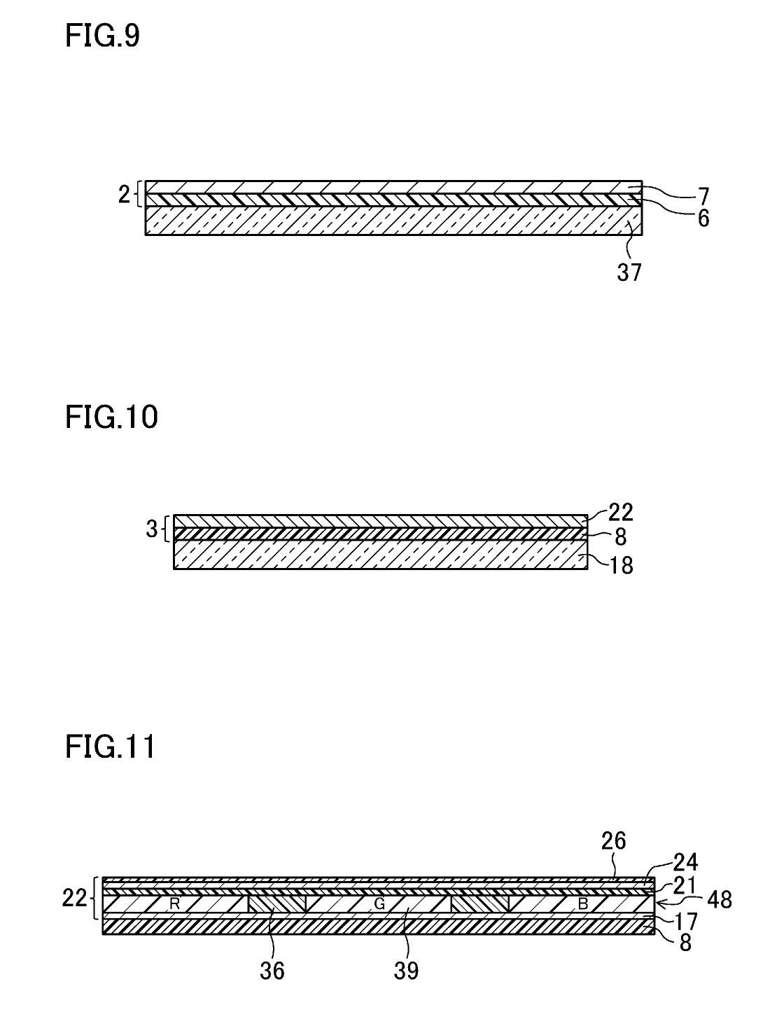

Next, a method for manufacturing the liquid crystal display device 1 according to the embodiment of the present invention will be described. FIGS. 9-13 are cross-sectional views illustrating the method for manufacturing a liquid crystal display device according to the embodiment of the present invention. The manufacturing method described below is a mere example, and is not intended to limit the liquid crystal display device 1 according to the present invention.

<TFT Substrate Fabrication Step>

(Plastic Substrate Formation Step)

First, as illustrated in FIG. 9, a glass substrate 37 having, for example, a thickness of about 0.7 mm is prepared as a support substrate.

Next, as illustrated in FIG. 9, on the glass substrate 37, a film-like plastic substrate 6 made of polyimide resin and having flexibility is formed to have, for example, a thickness of about 10 μm.

More specifically, first, a silane coupling agent for ensuring adhesion is applied to the glass substrate 37, and is then subjected to heat treatment. After that, on a surface of the glass substrate 37, an organic solvent (dimethyl acetamide, N-methyl pyrrolidone, etc.) including a precursor (polyamide acid) of polyimide resin which will be a material for the plastic substrate 6 is formed by coating.

Next, the glass substrate 37 is heated at about 100° C. to volatilize the organic solvent, and is subjected to thermal treatment at 250-350° C. for one hour to cause imidization reaction, thereby forming the plastic substrate 6 made of polyimide resin.

In order to prevent change in color (change into yellow) due to oxidation of the plastic substrate 6, thermal treatment (at about 250-350° C.) for imidization is performed in a nitrogen atmosphere having an oxygen concentration less than or equal to 100 ppm for about 1-3 hours, thereby obtaining the transparent plastic substrate 6.

Polyimide resin is obtained by imidization of polyamide acid from tetra carboxylic acid dianhydride and diamine.

Tetra carboxylic acid dianhydride and diamine have many kinds of monomers, which are broadly categorized into an aromatic series or alicyclic series. Therefore, polyimide resin which is any one of aromatic polyimide resin, aromatic-alicyclic polyimide resin, alicyclic-aromatic polyimide resin, or wholly alicyclic polyimide resin is formed as a combination. Polyimide resin of the alicyclic series forms no charge-transfer complex, and the transparency is improved while the heat resistance is maintained, and thus the polyimide resin is suitable for transmissive-type display devices.

Moreover, aromatic polyimide is generally colored yellow or yellowish brown. This is probably caused due to formation of charge-transfer complexes in molecules or between molecules of a tetra carboxylic acid component (acceptor) and a diamine component (donor).

Therefore, colorless and transparent polyimide resin will be obtained by inhibiting the formation of the charge-transfer complex. In particular, fluorinated aromatic polyimide is tetra carboxylic acid having a low degree of electron acceptance, is effective for excellent transparency in the visible light region, and is suitable to transmissive-type display devices.

Next, a base coat layer 9, a TFT 15, a pixel electrode 19, etc. are patterned on the plastic substrate 6, thereby forming a display element layer 7 as illustrated in FIG. 9. This will be described in detail below.

(Base Coat Layer Formation Step)

First, in order to remove particles, etc. on a surface of the plastic substrate 6 and clean the surface, a cleaning step is performed by using, for example, an organic solvent such as SPX, DMSO, or NMP. Next, as illustrated in FIG. 4, the base coat layer 9 made of, for example, silicon oxide (or silicon nitride) is formed on the plastic substrate 6 by plasma CVD (higher than or equal to 300° C.) to have a thickness of about 250 nm.

(Gate Electrode Formation Step)

Next, for example, a molybdenum film (having a thickness of about 150 nm), or the like is formed on the base coat layer 9 by sputtering. Then, photolithography, wet etching, and resist removal and cleaning are performed with respect to the molybdenum film, thereby forming gate interconnects 11, gate electrodes 27, and auxiliary capacitor interconnects 16 as illustrated in FIGS. 3 and 4.

Although the molybdenum film having a single layer structure is shown as a metal film forming the gate electrode 27 in the present embodiment, the gate electrode 27 may be formed with a thickness of 50 nm to 300 nm by, for example, a metal film such as an aluminum film, a tungsten film, a tantalum film, a chromium film, a titanium film, or a copper film, a film comprised of an alloy or nitride of such metals, or a layered structure of such films.

(Gate Insulating Film Formation Step)

Next, on the entire substrate on which the gate interconnects 11, the gate electrodes 27, and the auxiliary capacitor interconnects 16 have been formed, for example, a silicon nitride film (having a thickness of about 200-400 nm) is formed by CVD, thereby forming a gate insulating film 12 covering the gate interconnects 11, the gate electrodes 27, and the auxiliary capacitor interconnects 16 as illustrated in FIG. 4. The gate insulating film 12 may have a layered structure including two layers.

(Semiconductor Layer and Source Drain Formation Step)

Next, on the entire substrate on which the gate insulating film 12 has been formed, for example, an intrinsic amorphous silicon film (having a thickness of about 70-150 nm) and a phosphorus-doped e amorphous silicon film (having a thickness of about 40-80 nm) are successively formed by plasma CVD, and are then patterned by photolithography in an island-like pattern on the gate electrodes 27 as illustrated in FIG. 4, thereby forming a semiconductor formation layer in which an intrinsic amorphous silicon layer 23a and an e amorphous silicon layer 23b are stacked.

On the entire substrate on which the semiconductor formation layer has been formed, for example, an aluminum film, a titanium film, etc. are sequentially formed by sputtering, and are then patterned by photolithography, thereby forming source interconnects 14, source electrodes 28, and drain electrodes 29 to have a thickness of about 300 nm as illustrated in FIGS. 3 and 4.

Next, using the source electrodes 28 and the drain electrodes 29 as a mask, the n⁺ amorphous silicon layer 23b of the semiconductor formation layer is etched, thereby patterning channel regions and forming a semiconductor layer 23 and TFT elements 15 including the semiconductor layer 23 as illustrated in FIGS. 3 and 4.

(Passivation Film Formation Step)

Next, as illustrated in FIG. 4, on surfaces of the gate insulating film 12 and the TFT elements 15, a passivation film 40 made of an inorganic insulating film such as a silicon nitride film is formed by for example, plasma CVD to have a thickness of about 250 nm

(Via Hole Formation)

Next, parts of the passivation film 40 to which pixel electrodes are extended are removed by dry etching, thereby forming via holes 41 in the passivation film 40 to reach the drain electrodes 29 as illustrated in FIG. 4.

(Planarizing Film Formation Step)

Next, on the entire substrate on which the passivation film 40 has been formed, acrylic photosensitive resin is applied to have a thickness of about 2-3 μm by, for example, spin coating, thereby forming a transparent planarizing film 10 covering the TFT elements 15 and the passivation film 40 as illustrated in FIG. 4.

(Contact Hole Formation Step)

Next, on the planarizing film 10, a photomask having a predetermined pattern is formed by photolithography. Next, by using the photomask, exposure and development are performed, thereby forming contact holes (through holes) 30 in the planarizing film 10 to reach the drain electrodes 29 as illustrated in FIG. 4.

In the present embodiment, an interlayer insulating film is formed by the passivation film 40 and the planarizing film 10. However, the interlayer insulating film may be formed only by the planarizing film 10.

(Pixel Electrode Formation Step)

Next, on the entire substrate on which the planarizing film 10 has been formed, a transparent conductive film (having a thickness of about 100-200 nm), for example, an ITO film made of indium tin oxide, or an IZO film made of indium zinc oxide, is formed by sputtering. Then, photolithography, wet etching, and resist removal and cleaning are performed with respect to the transparent conductive film, thereby forming the pixel electrodes 19 as illustrated in FIG. 4.

At this time, the pixel electrodes 19 are formed on a surface of the planarizing film 10 to cover surfaces of the contact holes 30.

(Alignment Layer Formation Step)

Next, polyimide resin is applied to the entire substrate by a printing method and is then rubbed, thereby forming an alignment layer 20 as illustrated in FIG. 4. Next, on the entire substrate, a photo spacer made of an acrylic photosensitive resin is formed by, for example, photolithography to have a thickness of about 100 nm.

In the above-described manner, a TFT substrate 2 provided with the display element layer 7 including the TFT elements 15, etc. can be fabricated on the plastic substrate 6.

<CF Substrate Fabrication Step>

(Plastic Substrate Formation Step)

First, as illustrated in FIG. 10, a glass substrate 18 having, for example, a thickness of about 0.7 mm is prepared as a support substrate. Next, as illustrated in FIG. 10, a film-like plastic substrate 8 made of, for example, polyimide resin and having flexibility is formed on the glass substrate 18 in a manner similar to that in the TFT substrate fabrication step to have a thickness of about 20 μm.

Next, on the plastic substrate 8, a color filter 48 including colored layers 39 and a black matrix 36 is formed, and a common electrode 24, and the like are patterned, thereby forming a CF element layer 22 as illustrated in FIG. 10. This will be described in detail below.

(Base Coat Layer Formation Step)

First, in order to remove particles, etc. on a surface of the plastic substrate 8, and to clean the surface, a cleaning step is performed by using, for example, an organic solvent such as SPX, DMSO, or NMP. Next, as illustrated in FIG. 11, a base coat layer 17 made of, for example, silicon oxide (or silicon nitride) is formed on the plastic substrate 8 by plasma CVD (higher than or equal to 300° C.) to have a thickness of about 250 nm.

(Color Filter Formation Step)

On the entire substrate on which the base coat layer 17 has been formed, for example, positive photosensitive resin in which black pigment such as carbon fine particles has been dispersed is applied by spin coating. The applied photosensitive resin is exposed through a photomask, and is then developed and heated, thereby forming a black matrix 36 having a thickness of about 100 nm as illustrated in FIG. 11.

Next, on the substrate on which the black matrix 36 has been formed, acrylic photosensitive resin colored, for example, red, green, or blue is applied. The applied photosensitive resin is patterned by exposing through a photomask followed by development, thereby forming a colored layer 39 of a selected color (e.g., a red layer R). Further, for the other two colors, a similar step is repeated to form colored layers 39 of the other two colors (e.g., a green layer G and a blue layer B), thereby forming the color filter 48 including the red layer R, the green layer G, and the blue layer B as illustrated in FIG. 11.

(Planarizing Film Formation Step)

Next, on the substrate on which the color filter 48 has been formed, acrylic photosensitive resin is applied by spin coating, and the applied photosensitive resin is exposed through a photomask and is then developed, thereby forming a planarizing film 21 to have a thickness of 2.5 μm as illustrated in FIG. 11.

(Common Electrode Formation Step)

Next, on the entire substrate on which the planarizing film 21 has been formed, for example, an ITO film is formed by sputtering, and is then patterned by photolithography, thereby forming a common electrode 24 to have a thickness of about 100 nm as illustrated in FIG. 11.

(Alignment Layer Formation Step)

Next, on the entire substrate on which the common electrode 24 has been formed, polyimide-based resin is applied by a printing method and is then rubbed, thereby forming an alignment layer 26 to have a thickness of about 100 nm as illustrated in FIG. 11.

In the above-described manner, a CF substrate 3 including the CF element layer 22 can be fabricated.

<Step of Bonding TFT Substrate and CF Substrate>

First, a sealing material 5 made of ultraviolet-curable thermosetting resin, or the like is formed by using for example, a dispenser on the CF substrate 3 in a frame shape.

Next, in a region of the CF substrate 3 surrounded by the sealing material 5 formed on the CF substrate 3, a liquid crystal material forming a liquid crystal layer 4 is dropped.

Further, the CF substrate 3 on which the liquid crystal material has been dropped is bonded to the TFT substrate 2 under reduced pressure, thereby obtaining a bonded structure.

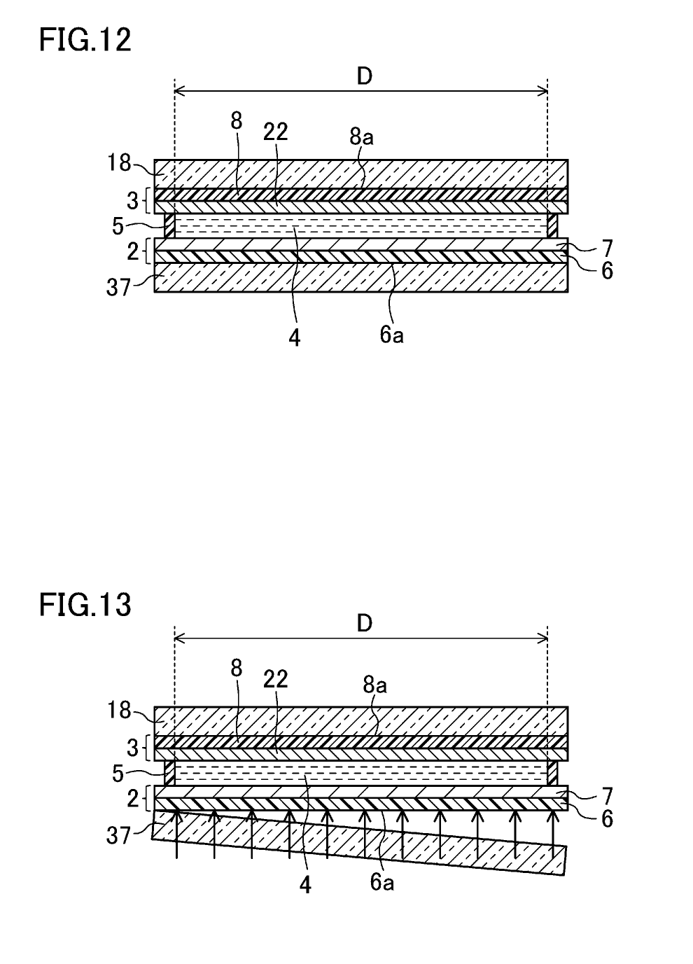

Next, the bonded structure is released to an atmospheric pressure, thereby pressurizing a surface and a back face of the bonded structure. Next, the sealing material 5 sandwiched by the bonded structure is irradiated with UV light, and then, the bonded structure is heated to cure the sealing material 5, thereby forming a bonded structure including the TFT substrate 2 and the CF substrate 3 bonded to each other as illustrated in FIG. 12. A material having only a thermosetting property may be used as a material for the sealing material 5.

<Glass Plate Removal Step>

Next, as illustrated in FIG. 13, irradiation with a laser beam (arrows in FIG. 13) is performed from the side of the glass substrate 37, thereby separating and removing the glass substrate 37 from the plastic substrate 6.

For example, XeCl laser (wavelength: 308 nm) can be uses as a laser beam. Due to the irradiation with a laser beam, an ablation (decomposition/vaporization of film due to heat absorption) phenomenon caused by absorption of the ultraviolet light occurs near the interface between the glass substrate 37 and the plastic substrate 6, so that a polymer structure in the plastic substrate 6 near the glass substrate 37 is broken (carbonized/vaporized), thereby the glass substrate 37 is separated from the plastic substrate 6.

The above-described ablation condition has to be set to correspond to the plastic substrate 6, and in general, the energy strength of the laser beam with which the plastic substrate 6 is irradiated is 300-3000 mW/cm², and about 1-10 shots of irradiation are performed. The laser beam transmittance of the plastic substrate 6 is lower than or equal to 1%, and the laser beam transmittance of the glass substrate 37 is higher than or equal to 30%.

Next, a polarizing plate 45 is adhered to a surface of the plastic substrate 6 from which the glass substrate 37 has been removed.

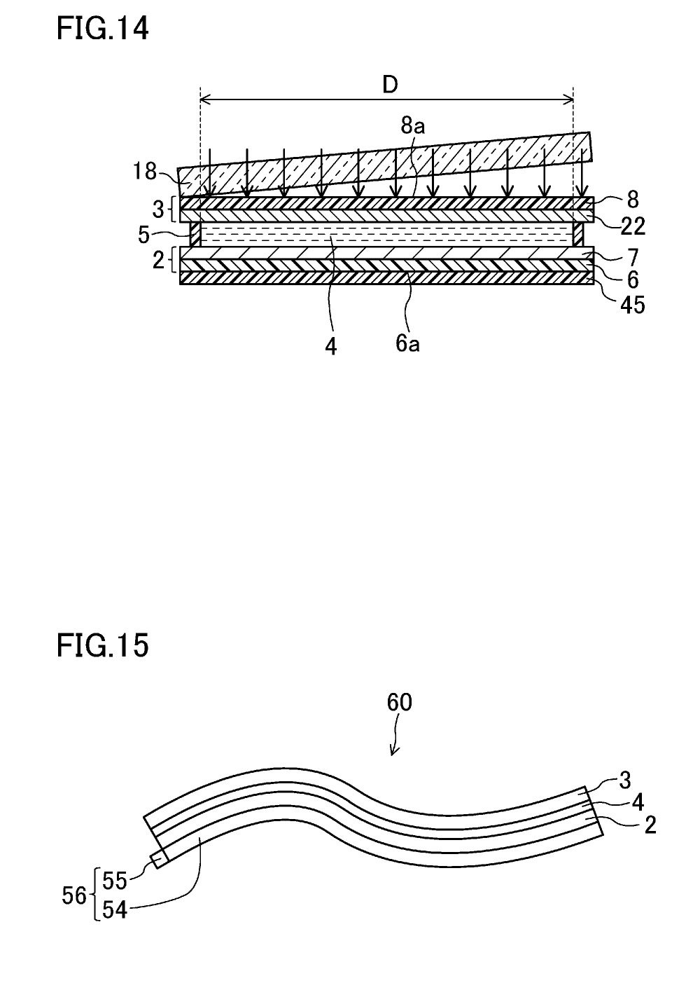

Next, in a similar manner, irradiation with a laser beam (arrows in FIG. 14) is performed from the side of the glass substrate 18, thereby separating and removing the glass substrate 18 from the plastic substrate 8.

The removal of the glass substrates 18, 37 is not necessarily performed by irradiation with a laser beam. For example, the glass substrates 18, 37 may be removed by using a polisher or an etching device.

Then, on a surface of the plastic substrate 8 from which the glass substrate 18 has been removed, a polarizing plate 46 is provided, thereby completing a liquid crystal display device 1 illustrated in FIGS. 1 and 2.

Even after the removal of the glass substrates 18, 37, the polarizing plates 45, 46 serve also as holders for preventing deformation such as a warp or waviness of the liquid crystal display device 1 which is thin and is provided with the plastic substrates 6, 8 having flexibility, the deformation being caused when the liquid crystal display device 1 is bent due to the self-weight of the liquid crystal display device 1.

With this configuration, since the polarizing plates 45, 46 serve also as holders, it is no longer necessary to provide a holder separately. Thus, the number of components can be reduced, thereby reducing costs, and the total thickness of the liquid crystal display device 1 can be reduced.

The present embodiment described above provides the following advantages.

(1) In the present embodiment, the plastic substrate 6 which has a thickness of 5-20 μm, and in which the expression (1) is satisfied is used. Therefore, even when the plastic substrate 6 is formed on the glass substrate 37 in the TFT substrate fabrication step, it is possible to reduce deformation such as a warp or waviness of the glass substrate 37 provided with the plastic substrate 6, the deformation being caused due to the difference in linear expansion coefficient between the glass substrate 37 and the plastic substrate 6. Thus, in the step of forming the display element layer 7, it is possible to reduce degradation in handleability of the glass substrate 37 provided with the plastic substrate 6, thereby preventing breakage or the like of the TFT substrate 2. Therefore, it is possible to prevent a reduction in productivity of the TFT substrate 2.

(2) In the TFT substrate fabrication step, deformation such as unevenness of the surface of the base coat layer 9 can be reduced, the deformation being caused due to the difference in linear expansion coefficient between the plastic substrate 6 and the base coat layer 9 formed on the plastic substrate 6. Thus, it is possible to prevent a reduction in transparency of the TFT substrate 2.

(3) In the present embodiment, polyimide resin is used as resin for forming the plastic substrate 6. Therefore, the plastic substrate 6 can be made of polyimide resin having excellent heat resistance.

(4) In the present embodiment, aromatic polyimide resin, cyclic aliphatic polyimide resin, and fluorinated aromatic polyimide resin is used as polyimide resin. Therefore, it is possible to form the plastic substrate 6 having excellent transparency in the visible light region.

(5) In the present embodiment, the polarizing plate 45 serving also as a holder preventing deformation of the TFT substrate 2 is provided on a surface of the plastic substrate 6 opposite to the display element layer 7. Therefore, the polarizing plate 45 serves also as a holder, and thus it is no longer necessary to provide a holder separately. Thus, the number of components can be reduced, thereby reducing costs, and the total thickness of the liquid crystal display device 1 can be reduced.

The embodiment may be modified as follows.

In the liquid crystal display device 1 of the embodiment, a backlight unit may be provided outside the polarizing plate 45. A backlight unit having flexibility can be used as the backlight unit.

For example, as illustrated in FIG. 15, a flexible backlight unit 56 including an edge light 55 including a light emitting diode and the like and a flexible light guide plate 54 made of transparent and thin silicone rubber, or the like may be combined with the TFT substrate 2, the CF substrate 3, and the liquid crystal layer 4 which are described above. As illustrated in FIG. 15, a liquid crystal display device 60 including the backlight unit 56 has flexibility and high designability.

In the embodiment, the polarizing plates 45, 46 serve also as holders preventing deformation of the liquid crystal display device 1. However, a holder may be provided in addition to the polarizing plates 45, 46.

In the embodiment, the transmissive liquid crystal display device 1 has been described as an example. However, the present invention is applicable to reflective liquid crystal display devices, semi transmissive liquid crystal display devices, etc.

An oxide semiconductor or an organic semiconductor such as ZnO, SnO, or IGZO may be used as a material for the semiconductor layer 23.

In the present embodiment, a liquid crystal display (LCD) device has been described as a display device. However, the display device may be an organic electro luminescence (EL) display device, an electrophoretic display device, a plasma display (PD) device, a plasma addressed liquid crystal (PALC) display device, an inorganic electro luminescence (EL) display device, a field emission display (FED) device, a surface-conduction electron-emitter display (SED) device, or the like.

### INDUSTRIAL APPLICABILITY

As described above, the present invention is useful particularly to display device substrates such as TFT substrates including plastic substrates.

### DESCRIPTION OF REFERENCE CHARACTERS

1 Liquid Crystal Display Device
2 TFT Substrate (Display Device Substrate)
3 CF Substrate (Another Display Device Substrate)
4 Liquid Crystal Layer (Display Medium Layer)
6 Plastic Substrate
6a Surface of Plastic Substrate Opposite to a Surface Provided with Terminals
7 Display Element Layer
8 Plastic Substrate
9 Base Coat Layer
10 Planarizing Film
12 Gate Insulating Film
15 TFT Element (Switching Element)
17 Base Coat Layer
18 Glass Substrate
22 CF Element Layer
27 Gate Electrode
28 Source Electrode
29 Drain Electrode
35 Liquid Crystal Display Element
37 Glass Substrate
40 Passivation Film
45 Polarizing Plate
46 Polarizing Plate
48 Color Filter
54 Flexible Light Guide Plate
55 Edge Light
56 Backlight Unit
60 Liquid Crystal Display Device

1. A display device substrate comprising:
a plastic substrate having flexibility; and
a display element layer provided on the plastic substrate and having a switching element, wherein
the plastic substrate has a thickness of 5-20 μm, and
the following expression is satisfied:
(Expression 1)
0≦D≦(2800×S^{-1.13})/T (1)
where
T is the thickness [μm] of the plastic substrate, S is a linear expansion coefficient [ppm/K] of resin forming the plastic substrate, and D is an elasticity modulus [GPa] of the resin.

2. The display device substrate of claim 1, wherein
the resin is polyimide resin.

3. The display device substrate of claim 2, wherein
the polyimide resin is one selected from the group consisting of aromatic polyimide resin, cyclic aliphatic polyimide resin, and fluorinated aromatic polyimide resin.

4. The display device substrate of claim 1, wherein
the display element layer includes a base coat layer provided on a surface of the plastic substrate.

5. The display device substrate of claim 1, further comprising:
a polarizing plate provided on a surface of the plastic substrate opposite to the display element layer, wherein
the polarizing plate serves also as a holder preventing deformation of the display device substrate.

6. The display device substrate of claim 1, wherein
the switching element is a TFT element.

7. A display device comprising:
the display device substrate of claim 1;
another display device substrate disposed to face the display device substrate, and
a display medium layer between the display device substrate and the another display device substrate.

8. The display device of claim 7, wherein
the display medium layer is a liquid crystal layer.
